(19) United States
(12) Patent Application Publication
(10) Pub. No.: US 2012/0119216 A1
(43) Pub. Date: May 17, 2012

(54) Semiconductor Device, Method of Manufacturing A Semiconductor Device, and Display Device

(76) Inventor: Tadahiro Ohmi, Miyagi (JP)

(21) Appl. No.: 13/386,928

(22) PCT Filed: Jul. 26, 2010
(86) PCT No.: PCT/JP2010/062491

§ 371 Date: Jan. 25, 2012

(30) Foreign Application Priority Data
Jul. 31, 2009 (JP) 2009-178533
Feb. 5, 2010 (JP) 2010-024786

(51) Int. Cl. H01L 33/08; H01L 21/28; H01L 23/48; H01L 29/786

(52) U.S. Cl. 257/59; 257/57; 438/591; 257/771; 257/734; 257/E33.053; 257/E21.19; 257/E29.291; 257/E23.01

(57) ABSTRACT

A semiconductor device comprises a gate electrode that is provided on a substrate and contains Al or an Al alloy; a gate insulating film that is so formed as to cover at least the upper surface of the gate electrode and contains an anodic oxide film that is obtained by anodizing the Al or Al alloy of the gate electrode; and an insulator layer that is so formed on the substrate as to surround the gate electrode and has a thickness that is substantially equal to a total of the thickness of the gate electrode and the thickness of the gate insulating film formed on the upper surface of the gate electrode.

### TECHNICAL FIELD

This invention relates to a semiconductor device, particularly a thin film transistor (TFT), and further relates to a manufacturing method thereof.

### BACKGROUND ART

Generally, a display device, such as a liquid crystal display device, an organic EL device, or an inorganic EL device is fabricated by successively forming and patterning films into conductive patterns such as a wiring pattern and an electrode pattern on a substrate having a flat main surface. Thus, the display device is manufactured by successively forming and patterning an electrode film, various films necessary for elements that constitute the display device, and so on.

In recent years, there is a growing demand for an increase in size with respect to this type of display device. In order to form a large-size display device, it is necessary to form more display elements on a substrate with high accuracy and to electrically connect these elements to a wiring pattern. In this case, insulating films, TFT (thin film transistor) elements, light emitting elements, and so on are formed, in addition to the wiring pattern, on the substrate in a multilayered state. As a result, level differences or steps are normally formed on the substrate in a stepwise fashion and the wiring pattern is arranged across these level differences. Further, when increasing the size of the display device, since the wiring pattern itself becomes longer, it is necessary to reduce the electrical resistance of the wiring pattern. As techniques for solving the level differences of the wiring pattern and reducing the resistance thereof, each of Patent Document 1 and Patent Document 2 discloses that, in order to form wiring for a flat panel display such as a liquid crystal display, a wiring pattern is formed on a surface of a transparent substrate and a transparent insulating material which is contacted with the wiring pattern and which is formed so as to have the same height as the wiring pattern.

### PRIOR ART DOCUMENT

### Patent Document

Patent Document 1: WO 2004/110117
Patent Document 2: JP-A-2007-43131

### SUMMARY OF THE INVENTION

### Problem to be Solved by the Invention

Patent Document 1 discloses that the characteristics of a display device can be improved by embedding wiring in a groove formed by a resin pattern to provide the thick film wiring, and further discloses techniques such as an inkjet method and a screen printing method as wiring forming methods. However, it has been found that the disclosed methods have a problem in adhesion to the substrate. Further, it has also been found that if the wiring is formed by a conductive ink, screen printing, or the like as described in Patent Document 1, a surface of the wiring becomes rough so that the flatness of an insulating layer or the like formed on the wiring is degraded. That is, when the wiring formed by the conductive ink or the screen printing is used as a gate electrode, there has been observed a phenomenon in which the propagation ratio of carriers passing through a channel is degraded due to the roughness of the wiring surface, thus making the high-speed operation difficult. Further, it has also been found that, using the conductive ink, the screen printing, or the like, when the wiring is fine, it is difficult to obtain a desired shape. For example, it has been found that even if an attempt is made to form a gate electrode with a width of 20 μm and a length of 50 μm by using such a method, an electrode material does not spread over the entire surface and thus it is practically impossible to form a desired pattern.

In order to solve these problems, Patent Document 2 proposes a manufacturing method which comprises at least a process of modifying a surface of an insulating substrate so as to enhance the adhesion, a process of forming a resin film on the insulating substrate, a process of patterning the resin film to form a recess for receiving therein an electrode or wiring, a process of applying a catalyst to the recess, a process of heat-curing the resin film, and a process of forming a conductive material in the recess by a plating method. A conductive metal layer, for example, a Cu layer, of a gate electrode or the like is formed by an electroless plating method and, thereon, as a Cu-diffusion suppressing layer, a W layer is formed by a selective CVD method or a Ni layer is formed by the electroless plating method, thereby forming the gate electrode. According to this method, the adhesion of the gate electrode to the substrate is improved and, further, even in the case of a gate electrode with a width of 20 μm and a length of 50 μm, it is possible to form a desired pattern regardless of the size.

However, it has been found that, even with this method, a surface of the gate electrode is rough so that the flatness of a gate insulating layer formed on the gate electrode is poor. At any rate, it has been difficult to make the gate insulating layer extremely thin, thus causing a reduction in the current drive capability of a TFT.

Further, there has also been observed a phenomenon in which a gap is formed between the plated layer and the surrounding resin film. This might be caused to occur by the fact that the resin expands due to high temperatures in the plating treatment and then shrinks after the plating formation. A disadvantage has been found such that such a gap results in local concentration of an electric field on the gate insulating film and brings about dielectric breakdown so that the gate electrode and a channel region are shortened to each other.

This invention is intended to solve at least one of the above-mentioned problems.

Specifically, this invention is intended to obtain a thin film transistor (TFT) which is excellent in flatness of a gate insulating film, and a manufacturing method thereof.

Further, this invention is intended to obtain a semiconductor device which is free of problems of the roughness of a surface of a gate electrode and a gap between the gate electrode and a surrounding insulating layer, and a manufacturing method thereof.

This invention is intended to obtain an insulated gate transistor having a gate insulating layer which is extremely thin and excellent in electrical properties, and a manufacturing method thereof.

### Means for Solving the Problem

Hereinbelow, aspects of this invention will be listed.

According to a first aspect of this invention, there is provided a semiconductor device characterized by comprising a gate electrode that is provided on a substrate and contains Al or an Al alloy, a gate insulating film that is provided so as to cover at least an upper surface of the gate electrode and includes an anodic oxide film obtained by anodizing the Al or the Al alloy of the gate electrode, and an insulator layer that is provided on the substrate so as to surround the gate electrode and which has a thickness that is substantially equal to a total of a thickness of the gate electrode and a thickness of the gate insulating film on the upper surface of the gate electrode.

According to a second aspect of this invention, there is provided the semiconductor device according to the first aspect, characterized in that the gate electrode contains the Al alloy which contains at least Zr and Ce among Mg, Zr, and Ce.

According to a third aspect of this invention, there is provided a semiconductor device comprising a gate electrode containing an Al alloy and a gate insulating film including an anodic oxide film that is obtained by anodizing the Al alloy of the gate electrode, characterized in that the Al alloy contains at least Zr and Ce among Mg, Zr, and Ce.

Herein, the Al alloy member used in the second and third aspects of this invention is an Al—Mg—Zr—Ce alloy in which, in mass %, the Mg concentration is 5.0% or less, the Ce concentration is 15% or less, the Zr concentration is 0.15% or less, the balance comprises Al and unavoidable impurities, and elements of the unavoidable impurities are respectively 0.01% or less. The elements of the unavoidable impurities are mainly Si, Fe, and Cu and, in addition, Mn, Cr, Zn, and so on are unavoidably incorporated from material ingots, scraps, tools, and so on when casting the alloy. In order to obtain the alloy of such purity, it is preferable to carry out casting using, for example, ingots of high-purity Al with an Al purity of 99.98 mass % or more obtained by the segregation process, the trinal electrolytic process, or the like.

Preferably, the Al alloy member used in the second and third aspects of this invention is such that, in mass %, the Mg concentration is more than 0.01% and 5.0% or less, the Ce concentration is more than 0.01% and 5.0% or less, the Zr concentration is more than 0.01% and 0.15% or less, the balance comprises Al and unavoidable impurities, and elements of the unavoidable impurities are respectively 0.01% or less. Also in this preferable example, the elements of the unavoidable impurities are, for example, Si, Fe, Cu, and so on. These impurities are normally incorporated in a general-purpose Al alloy in an amount less than about 0.5%, but since this causes a bad influence such as impairing the uniformity of a film formed by anodization, the impurities should be 0.01% or less. An anodic oxide film of an aluminum alloy, particularly an aluminum oxide film formed by later-described anodization using a non-aqueous solution, has high thermal stability, is dense and thus free of formation of voids, defects of gas accumulation, or the like, and is extremely excellent in corrosion resistance to chemicals and a halogen gas, particularly a chlorine gas, and therefore, it has excellent electrical properties such as high dielectric strength and small leakage current. Further, since it can be formed as an extremely thin film of about 0.1 μm, the current drive capability of a transistor is significantly improved.

According to a fourth aspect of this invention, there is provided the semiconductor device according to any one of the first to the third aspects, characterized in that the anodic oxide film is a non-porous anodic oxide film formed by anodization using a non-aqueous solution.

A method of the anodization using the non-aqueous solution will be described in detail later.

According to a fifth aspect of this invention, there is provided the semiconductor device according to any one of the first, the second, and the fourth aspects, characterized in that the substrate is a substantially transparent insulator substrate and the insulator layer is a substantially transparent resin layer.

According to a sixth aspect of this invention, there is provided the semiconductor device according to the fifth aspect, characterized in that the resin layer contains one or more kinds of resins selected from the group consisting of an acrylic-based resin, a silicone-based resin, a fluorine-based resin, a polyimide-based resin, a polyolefin-based resin, an alicyclic olefin-based resin, and an epoxy-based resin.

According to a seventh aspect of this invention, there is provided the semiconductor device according to the fifth aspect, characterized in that the resin layer is formed of an alkali-soluble alicyclic olefin-based resin composition.

According to an eighth aspect of this invention, there is provided the semiconductor device according to the fifth aspect, characterized in that the substrate comprises an alkali glass and an alkali diffusion preventing film formed thereon.

According to a ninth aspect of this invention, there is provided the semiconductor device according to the eighth aspect, characterized in that the alkali diffusion preventing film is a substantially transparent insulator coating film.

According to a tenth aspect of this invention, there is provided the semiconductor device according to the ninth aspect, characterized in that the insulator coating film is a film that is obtained by drying and baking a liquid coating film containing at least one of a metal organic compound and a metal inorganic compound and a solvent.

According to an eleventh aspect of this invention, there is provided the semiconductor device according to any one of the first to the tenth aspects, characterized in that the gate electrode has a two-layer structure comprising an Al layer and a layer of an Al alloy containing at least Zr and Ce among Mg, Zr, and Ce and the gate insulating layer includes a film formed by anodizing the Al alloy.

According to a twelfth aspect of this invention, there is provided a method of manufacturing a semiconductor device, characterized by comprising a step of forming a gate electrode film in a predetermined pattern on a substantially transparent substrate using Al or an Al alloy, a step of anodizing a surface of the gate electrode by an anodization method using a non-aqueous solution, and a step of providing on the substrate a transparent insulator layer having a thickness substantially equal to a total of a thickness of the gate electrode and a thickness of an anodic oxide film on its upper surface so as to surround the gate electrode.

Preferably, the step of anodizing by the anodization method using the non-aqueous solution comprises a step of forming a non-porous amorphous aluminum oxide passive or inactive film by anodization in an anodization solution containing an organic solvent which has a dielelctric constant smaller than that of water and which dissolves water. The dielectric constant of water is about 80. Since the binding energy of a material is inversely proportional to the square of the dielectric constant, water is dissociated even at 0° C. in an HF solution having a higher dielectric constant of, for example, 83.

Accordingly, in order to prevent decomposition of water and thus to prevent etching of a grown aluminum oxide film, anodization should be carried out in an anodization solution containing an organic solvent with a low vapor pressure which has a dielectric constant smaller than that of water and which dissolves water. As a result, it is possible to form a non-porous amorphous aluminum oxide passive film.

As examples of such an organic solvent, ethylene glycol has a dielectric constant of 39, diethylene glycol has a dielectric constant of 33, triethylene glycol has a dielectric constant of 24, and tetraethylene glycol has a dielectric constant of 20. Therefore, using this organic solvent, it is possible to effectively reduce the dielectric constant and thus to apply a high voltage without causing electrolysis of water. For example, if ethylene glycol is used, the anodization voltage can be applied up to a maximum of 200V without causing electrolysis of water so that it is possible to form a non-porous amorphous aluminum oxide passive film having a thickness of 0.3 μm. If diethylene glycol is used, the anodization voltage can be applied up to a maximum of 300V without causing electrolysis of water so that it is possible to form a non-porous amorphous aluminum oxide passive film having a thickness of 0.4 μm.

An electrolyte is added to the anodization solution for making the anodization solution electrically conductive. However, if the anodization solution becomes acidic as a result thereof, the aluminum member is corroded. Therefore, use is made of an electrolyte that can provide a pH of 4 to 10, preferably 5.5 to 8.5, and more preferably 6 to 8 to prevent corrosion of aluminum while enhancing the electrical conductivity of the anodization solution. Such an electrolyte may be, for example, adipate. The content thereof is 0.1 to 10 wt % and is preferably about 1%. As a typical example, use is made of an anodization solution containing 79% organic solvent, 20% water, and 1% electrolyte.

Herein, the pH of the anodization solution is 4 or more, preferably 5 or more, and more preferably 6 or more and is normally 10 or less, preferably 9 or less, and more preferably 8 or less. In order to prevent a metal oxide film formed by anodization from being dissolved in an anodization solution, the pH thereof is preferably close to neutral.

An anodization solution for use in this invention preferably shows a buffer action in the range of pH 4 to 10 in order to buffer or alleviate the change in concentration of various substances in the anodization solution and to maintain the pH in a predetermined range. Accordingly, it is preferable to contain a compound, such as an acid or a salt that shows a buffer action. The kind of such a compound is not particularly limited, but in terms of high solubility and high dissolution stability in the anodization solution, it is preferably at least one kind selected from the group consisting of boric acid, phosphoric acid, organic carboxylic acid, and salts thereof. More preferably, it is an organic carboxylic acid with almost no remaining boron or phosphorus element in an anodic oxide film, or a salt thereof.

Solute components of an extremely small amount are incorporated into an oxide film formed by anodization, but using the organic carboxylic acid or its salt as a solute, there is no possibility of elution of boron or phosphorus element from the oxide film. This makes it possible to improve the quality of the formed thin film and to stabilize and improve the performance of a device or the like using the thin film. Tartaric acid, citric acid, and adipic acid are particularly preferable in terms of solution stability, safety, excellent buffer action, and so on. Among them, one kind may be used or two or more kinds may be used in combination.

The concentration of these compounds is normally set to 0.01 mass % or more, preferably 0.1 mass % or more, and more preferably 1 mass % or more relative to the entire anodization solution. In order to increase the electrical conductivity to sufficiently carry out the formation of the oxide film, a higher concentration is preferable. However, the compound concentration is normally set to 30 mass % or less, preferably 15 mass % or less, and more preferably 10 mass % or less. In order to keep the performance of the oxide film high and to suppress its cost, it is preferable that the concentration is not greater than the above.

An anodization solution for use in this invention preferably contains a non-aqueous solvent. If the anodization solution containing the non-aqueous solvent is used, there is an advantage in that the treatment can be carried out with high throughput. This is because the time required for constant current anodization can be shortened as compared with the case where an aqueous based anodization solution is used.

As the non-aqueous solvent of the anodization solution for use in the formation of an anodic oxide film, ethylene glycol, propylene glycol, or diethylene glycol, as described above, is particularly preferable and these may be used alone or in combination. Further, if the non-aqueous solvent is contained, water may be contained.

The content of the non-aqueous solvent is normally 10 mass % or more, preferably 30 mass % or more, more preferably 50 mass % or more, and particularly preferably 55 mass % or more relative to the entire anodization solution. However, the content of the non-aqueous solvent is normally 95 mass % or less, preferably 90 mass % or less, and particularly preferably 85 mass % or less.

When the anodization solution contains water in addition to the non-aqueous solvent, the content of the water is normally 1 mass % or more, preferably 5 mass % or more, more preferably 10 mass % or more, and particularly preferably 15 mass % or more relative to the entire anodization solution, while, it is normally 85 mass % or less, preferably 50 mass % or less, and particularly preferably 40 mass % or less.

The ratio of the water to the non-aqueous solvent is preferably 1 mass % or more, preferably 5 mass % or more, more preferably 7 mass % or more, and particularly preferably 10 mass % or more, while, it is normally 90 mass % or less, preferably 60 mass % or less, more preferably 50 mass % or less, and particularly preferably 40 mass % or less.

The step of anodizing by the anodization method using the non-aqueous solution in the respective aspects of this invention preferably comprises a step of carrying out anodization at a constant current until reaching a predetermined anodization voltage Vf and, after reaching the anodization voltage Vf, carrying out anodization while maintaining the voltage Vf for a fixed time.

In this event, in order to efficiently form an oxide film, the current density is normally set to 0.001 mA/cm² or more and preferably 0.01 mA/cm² or more. However, in order to obtain an oxide film with excellent surface flatness, the current density is normally set to 100 mA/cm² or less and preferably 10 mA/cm² or less.

The anodization voltage Vf is normally set to 3V or more, preferably 10V or more, and more preferably 20V or more. The thickness of an oxide film to be obtained is related to the anodization voltage Vf and, therefore, in order to give a certain thickness to the oxide film, it is preferable to apply the above voltage or higher. However, the anodization voltage Vf is normally set to 1000V or less, preferably 700V or less, and more preferably 500V or less. Since the oxide film to be obtained has high dielectric properties, anodization is preferably carried out at the above voltage or less in order to form the high-quality oxide film without causing dielectric breakdown.

According to a thirteenth aspect of this invention, there is provided the method of manufacturing the semiconductor device according to the twelfth aspect, characterized in that the step of providing the transparent insulator layer on the substrate comprises a step of forming a material, that forms the transparent insulator film, so as to extend over the gate electrode from the transparent substrate and a step of removing a surface of the material, that forms the transparent insulator film, using a plasma containing oxygen.

According to a fourteenth aspect of this invention, the method of manufacturing the semiconductor device according to thirteenth aspect, characterized in that the step of removing using the plasma comprises a step of exposing the anodic oxide film on the gate electrode and a step of modifying the exposed anodic oxide film by the plasma.

According to a fifteenth aspect of this invention, there is provided the method of manufacturing the semiconductor device according to any one of the twelfth to the fourteenth aspects, characterized in that the gate electrode film has a two-layer structure comprising an Al layer and a layer of an Al alloy containing at least Zr and Ce among Mg, Zr, and Ce and a gate insulating layer includes a film formed by anodizing the Al alloy.

According to a sixteenth aspect of this invention, there is provided a display device manufactured using the semiconductor device according to any one of the first to the eleventh aspects.

According to a seventeenth aspect of this invention, there is provided a display device characterized by comprising wiring that is provided on a substrate and contains Al or an Al alloy, an insulating film that is provided so as to cover at least an upper surface of the wiring and includes an anodic oxide film formed by anodizing the Al or the Al alloy forming the wiring, and an insulator layer that is provided on the substrate so as to surround the wiring and has a thickness that is substantially equal to a total of a thickness of the wiring and a thickness of the insulating film on the upper surface of the wiring.

### Effect of the Invention

According to this invention, by providing a patterned Al or Al alloy gate electrode with an anodic oxide film attached thereto as a gate insulating film, using a non-aqueous solution and by burying a region around the gate insulating film with an insulating film and flattening it, it is possible to solve various problems which arise when a gate electrode is formed in a groove after the groove is formed on an insulator. Thus, it is possible to achieve high carrier mobility with the flat and thin gate insulating film. Further, using an Al—Zr—Ce alloy or an Al—Mg—Zr—Ce alloy as a gate electrode and using, as a gate insulating film, an anodic oxide film obtained by anodizing a surface of the gate electrode using a non-aqueous solution, it is possible to provide an insulated gate transistor having very high carrier mobility due to the gate insulating film which is thin and excellent in electrical properties.

### BRIEF DESCRIPTION OF THE DRAWINGS

FIG. 1 is a cross-sectional view showing the structure of a thin film transistor according to a first embodiment of this invention.

FIG. 2 shows cross-sectional views (a) to (g) for explaining, in order of process, an example of a method of manufacturing the thin film transistor according to the first embodiment of this invention.

FIG. 3 shows cross-sectional views (a) to (h) for explaining, in order of process, another example of a method of manufacturing the thin film transistor according to the first embodiment of this invention.

FIG. 4 is a cross-sectional view for explaining a process subsequent to the processes of FIG. 2 or FIG. 3 in the method of manufacturing the thin film transistor according to the first embodiment of this invention.

FIG. 5 is a cross-sectional view showing the structure of a thin film transistor according to a second embodiment of this invention.

### MODE FOR CARRYING OUT THE INVENTION

A first embodiment of this invention will be described with reference to the figures.

### First Embodiment

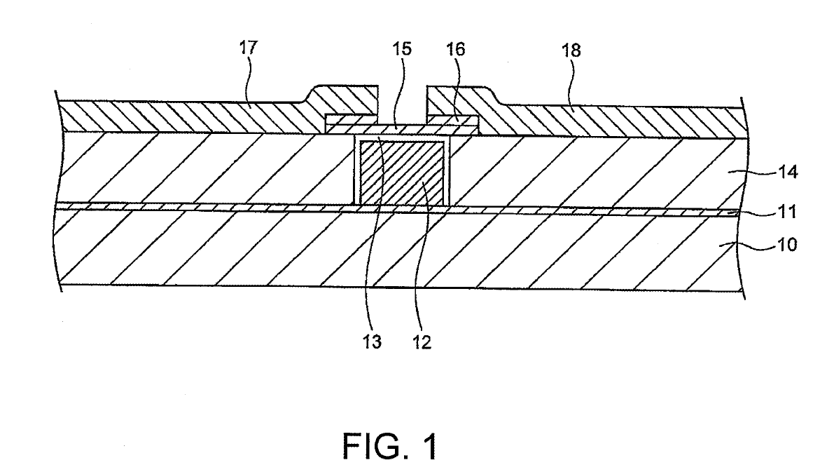

FIG. 1 is a cross-sectional view showing an example of the structure of a thin film transistor (TFT) of this invention. The thin film transistor comprises a Na-diffusion preventing film 11 formed on a glass substrate (insulating substrate) 10, a gate electrode/wiring layer 12 (gate electrode portion is shown in the figure) of Al or an Al alloy formed in a predetermined pattern on the Na-diffusion preventing film 11, a dense anodic oxide film 13 formed on surfaces of the gate electrode 12 by anodization using a non-aqueous solution, a transparent resin layer 14 formed around the gate electrode/wiring layer 12 to approximately the same height as the gate electrode 12 and its upper-surface anodic oxide film 13 so as to be substantially flush with the upper-surface anodic oxide film 13, a semiconductor layer 15 formed over the gate electrode 1 through the gate insulating film 13, and a source electrode 17 and a drain electrode 18 respectively connected to electrode connection regions 16 of the semiconductor layer 15.

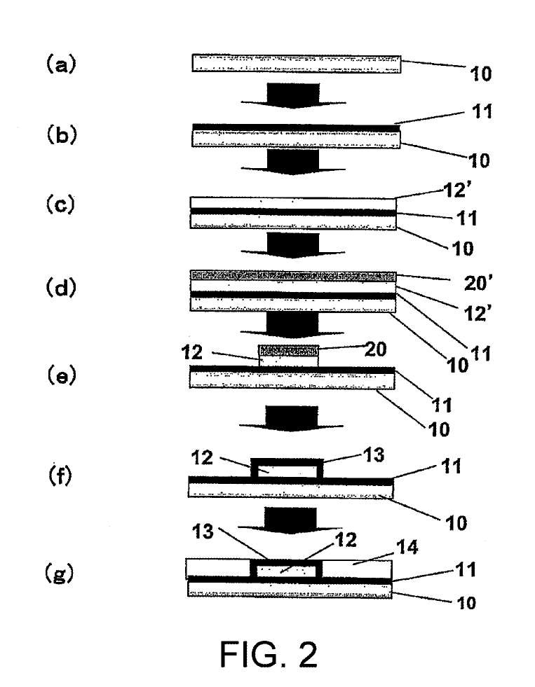

Next, a method of forming a thin film transistor of this embodiment configured as described above will be described with reference to the figures. FIG. 2 (a) to (g) are exemplary diagrams showing one example of the method of manufacturing this thin film transistor in order of process. First, referring to FIG. 2(a), an inexpensive soda glass or alkali glass substrate 10 is prepared as a substrate. This glass substrate 10 may be a large-size substrate that can form a large-size screen of 30 inches or more. This glass substrate 10 is treated with a 0.5 vol % hydrofluoric acid aqueous solution for 10 seconds and then washed with pure water to remove, by lift-off, surface contamination. Then, as shown in FIG. 2(b), a solution in which a composition of ((CH₃)SiO_{3/2})ₓ(SiO₂)₁₋ₓ (where 0<x≦1.0) is dissolved in an organic solvent is coated on a surface of the soda glass substrate 10 using a slit coater. Then, heating is carried out at a reduced pressure to completely remove the solvent. Specifically, heating is carried out at 400° C. at a reduced pressure of 1 to 5 Torr (133 to 665 Pa). A transparent alkali diffusion preventing layer 11 with a thickness of 0.2 μm thus formed has insulating properties which are specified by excellent values of current density of 1×10⁻¹⁰ A/cm² at 1 MV/cm, current density of 1×10⁻⁹ A/cm² at 3 MV/cm, and current density of 1×10⁻⁸ A/cm² even at 5 MV/cm. Further, it has been confirmed that, in a film thickness range of 150 to 300 nm, the sodium diffusion preventing performance of this coating-type alkali diffusion preventing film 11 shows almost no difference, after baking and after annealing, in sodium diffusion into the film 11 from the glass substrate 10 containing sodium and thus can completely prevent the diffusion of the sodium.

Then, referring to FIG. 2(c), an Al alloy layer 12′ is formed by sputtering to a thickness of 2 to 3 μm on the alkali diffusion preventing film 11 on the substrate. Then, a photoresist 20′ is coated thereon as shown in FIG. 2(d) and, as shown in FIG. 2(e), the resist is left in a predetermined pattern 20 by known exposure and development. Thereafter, using it as a mask, the Al alloy layer 12′ is shaped into a predetermined gate electrode/wiring pattern 12 by dry etching. Then, the resist 20 is removed and, as shown in FIG. 2(f), anodization using a non-aqueous solution, as was described above, is applied to surfaces of the Al alloy 12, thereby forming an anodic oxide film 13.

Herein, in the formation of the Al alloy layer 12′ in this embodiment, an Al alloy for use as a sputtering target is an Al—Mg—Zr—Ce alloy in which, in mass %, the Mg concentration is 5.0% or less, the Ce concentration is 15% or less, the Zr concentration is 0.15% or less, the balance comprises Al and unavoidable impurities, and elements of the unavoidable impurities are respectively 0.01% or less. In this embodiment, the elements of the unavoidable impurities are mainly Si, Fe, and Cu and, in addition, Mn, Cr, Zn, and so on are unavoidably incorporated from material ingots, scraps, tools, and so on when casting the alloy. In order to obtain the alloy of such purity, it is preferable to carry out casting using, for example, ingots of high-purity Al with an Al purity of 99.98 mass % or more obtained by the segregation process, the trinal electrolytic process, or the like.

Preferably, the Al alloy layer 12′ formed according to this embodiment is such that, in mass %, the Mg concentration is more than 0.01% and 5.0% or less, the Ce concentration is more than 0.01% and 5.0% or less, the Zr concentration is more than 0.01% and 0.15% or less, the balance comprises Al and unavoidable impurities, and elements of the unavoidable impurities are respectively 0.01% or less. Also in this preferable example, the elements of the unavoidable impurities are, for example, Si, Fe, Cu, and so on. These impurities are normally incorporated in a general-purpose Al alloy in an amount less than about 0.5% or so, but since such impurities adversely affect the uniformity of a film formed by anodization, the impurities should be reduced to 0.01% or less.

In the Al alloy according to the preferable example, the mechanical strength is improved with the addition of 5.0% or less Mg. By adding about 0.15% or less Zr, the grain growth is suppressed even if a heat treatment is carried out at about 350° C. so that the mechanical strength is maintained. The Vickers hardness is improved by adding Ce up to about 15.0%. If the Ce addition amount exceeds 5.0%, “cavities” (voids) are formed in the member and therefore the Ce addition amount is preferably 5.0% or less, while, “cavities” (voids) can be removed by HIP (Hot Isostatic Pressing) treatment.

In this embodiment, on the surfaces of the Ce-added Al alloy layer 12, an amorphous Al₂O₃ film is formed to about 0.1 μm to 0.6 μm as the anodic oxide film 13 by the anodization using the non-aqueous solution. The non-aqueous solution used contains ethylene glycol or diethylene glycol as a solvent and contains pure water and adipic acid as solutes. The anodic oxide film 13 is preferably as thin as possible as the gate insulating film and thus is set to a thickness of 0.1 μm.

Constant current anodization was carried out for a Ce-added Al alloy (4.5% Mg-1% Ce-0.1% Zr), a Ce-free Al alloy (4.5% Mg-0.1% Zr), another Ce-free Al alloy (5% Mg-0.1% Zr), and another Ce-added Al alloy (4.5% Mg-5% Ce-0.1% Zr) at a current density of 1 mA/cm² until the voltage reaches 200V and then, continuously, constant voltage anodization was carried out while maintaining the voltage at 200V. As a result, as compared with the Ce-free Al alloy (4.5% Mg-0.1% Zr), in the case of the Ce-added Al alloy (4.5% Mg-1% Ce-0.1% Zr), the current density decreases when the elapsed time exceeds about 600 seconds so that the anodization characteristics (change in anodization current with respect to the time) are improved.

Further, even as compared with the other Ce-free Al alloy (5% Mg-0.1% Zr), in the case of the Ce-added Al alloy (4.5% Mg-1% Ce-0.1% Zr), the anodization current decreases when the elapsed time exceeds about 750 seconds so that the anodization characteristics are improved.

Further, in the case where the above-mentioned anodic oxide film is formed on a surface of the Ce-added Al alloy (4.5% Mg-1% Ce-0.1% Zr), the anodization current can be smaller in comparison with the case where the above-mentioned anodic oxide film is formed on a surface of the other Ce-added Al alloy (4.5% Mg-5% Ce-0.1% Zr). This might be because the surface to be anodized is flatter (with less “cavities” (voids)) in the Ce-added Al alloy (4.5% Mg-1% Ce-0.1% Zr) than in the other Ce-added Al alloy (4.5% Mg-5% Ce-0.1% Zr).

The above-mentioned anodic oxide films were exposed to a chlorine gas (Cl₂ gas) and the resistance thereof to the chlorine gas was observed. As a result, the anodic oxide films formed on the surfaces of the Ce-added Al alloy (4.5% Mg-1% Ce-0.1% Zr) and the other Ce-added Al alloy (4.5% Mg-5% Ce-0.1% Zr) were significantly greater in corrosion resistance to the chlorine gas than the anodic oxide films formed on the surfaces of the Ce-free Al alloy (4.5% Mg-0.1% Zr) and the other Ce-free Al alloy (5% Mg-0.1% Zr). That is, the weight loss ratio due to corrosion was 0.87% in the anodic oxide film formed on the surface of the Ce-free Al alloy (4.5% Mg-0.1% Zr) while the weight loss ratios due to corrosion were 0.02% or less in the anodic oxide film formed on the surface of the Ce-added Al alloy (4.5% Mg-1% Ce-0.1% Zr) and 0.01% in the anodic oxide film formed on the surface of the other Ce-added Al alloy (4.5% Mg-5% Ce-0.1% Zr). It has been confirmed that the corrosion resistance is improved as the Ce concentration increases. Being excellent in corrosion resistance as described above shows the denseness and high quality of the film and thus such an anodic oxide film has excellent electrical properties such as high breakdown voltage and small leakage current.

Then, as shown in FIG. 2(g), a solution is coated around the gate electrode/wiring layer 12. The solution includes one or more kinds of resins selected from the group consisting of an acrylic-based resin, a silicone-based resin, a fluorine-based resin, a polyimide-based resin, a polyolefin-based resin, an alicyclic olefin-based resin, and an epoxy-based resin which are dissolved in the solvent. The solution is coated around the gate electrode/wiring layer 12 to approximately the same height as the gate electrode 12 and its upper-surface anodic oxide film 13 by the use of a slit coater and then is dried, thereby forming a transparent resin layer 14 which is substantially flush with the upper-surface anodic oxide film 13. As the resin, it is preferable to use an alkali-soluble alicyclic olefin-based resin composition.

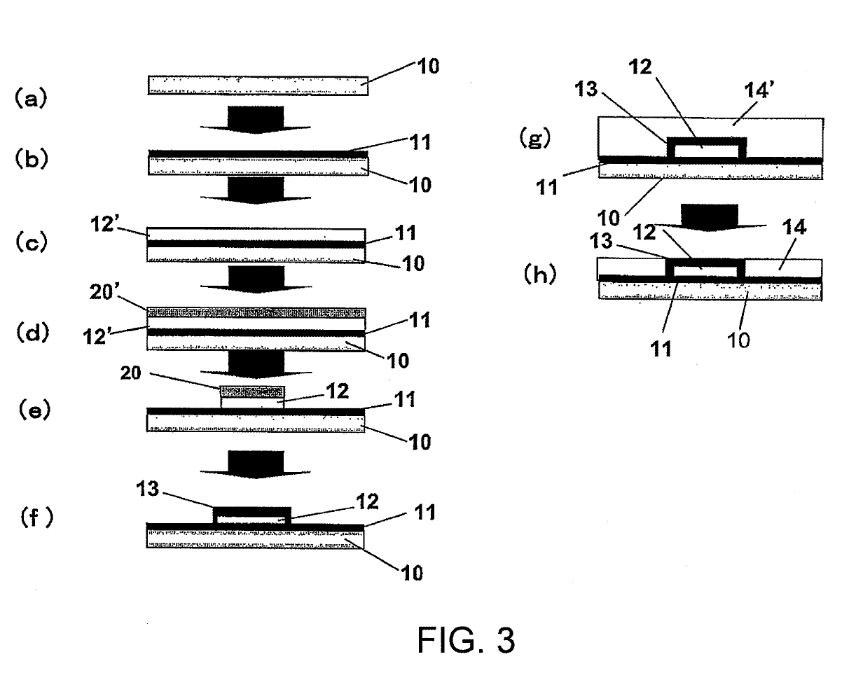

Next, referring to FIG. 3 (a) to (h), another embodiment of a method of manufacturing a thin film transistor according to this invention will be described. Since processes of FIG. 3 (a) to (f) are respectively the same as the processes of FIG. 2 (a) to (f), explanation thereof would be omitted. Referring to FIG. 3(g), herein, a transparent resin film 14′ is formed so as to exceed the height of the gate electrode/wiring 12 and the gate insulating film 13 on the upper surface thereof. Then, the substrate 10 formed with the transparent resin film 14′ and the others is placed in a microwave-excited plasma processing apparatus, then a krypton gas and an oxygen gas are introduced into the apparatus, and further a microwave is introduced into the apparatus to generate a plasma, thereby removing a surface of the transparent resin film 14′ by etch-back to expose a surface of the gate insulating film 13 as shown in FIG. 3(h). In this event, the exposed surface of the gate insulating film 13 is exposed to oxygen radicals generated by the plasma and is oxidized so that the film quality is improved.

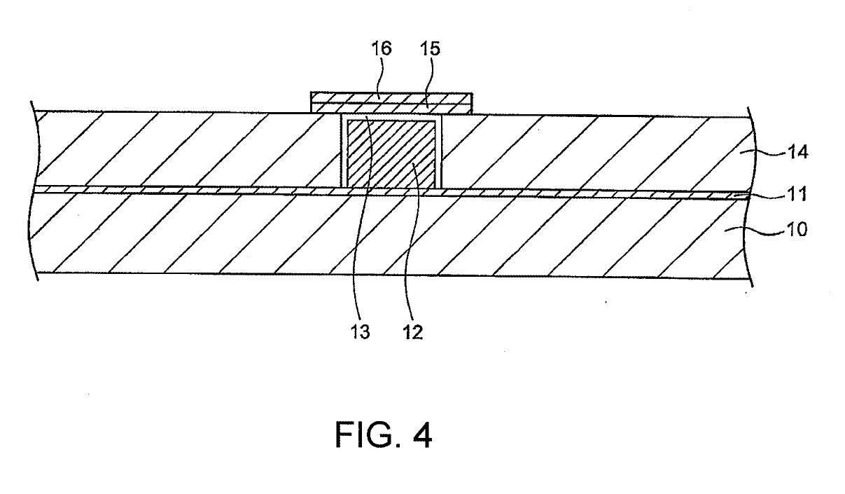

Then, referring to FIG. 4, subsequently to the process of FIG. 2(g) or the process of FIG. 3(h), an amorphous silicon film 15 and an n+ amorphous silicon film 16 were continuously deposited so as to cover the gate electrode 12 through the gate insulating film 13 by a PECVD method using a metal-surface microwave-excited plasma processing apparatus (MSEP) and then the amorphous silicon films 15 and 16 were partly removed except at a portion over the gate electrode 12 and its peripheral portion by a photolithography method and a known RIE method.

Subsequently, as shown in FIG. 1, film formation was carried out in order of Ti, Al, and Ti by a known sputtering method or the like for obtaining a source electrode and a drain electrode and then patterning was carried out by the photolithography method, thereby forming a source electrode 17 and a drain electrode 18. Then, using the formed source electrode 17 and drain electrode 18 as a mask, the n+ amorphous silicon film 16 was etched by a known technique, thereby separating a source region and a drain region. Then, a silicon nitride film (not illustrated) was formed as a protective film by the known PECVD method, thereby completing a thin film transistor of this embodiment.

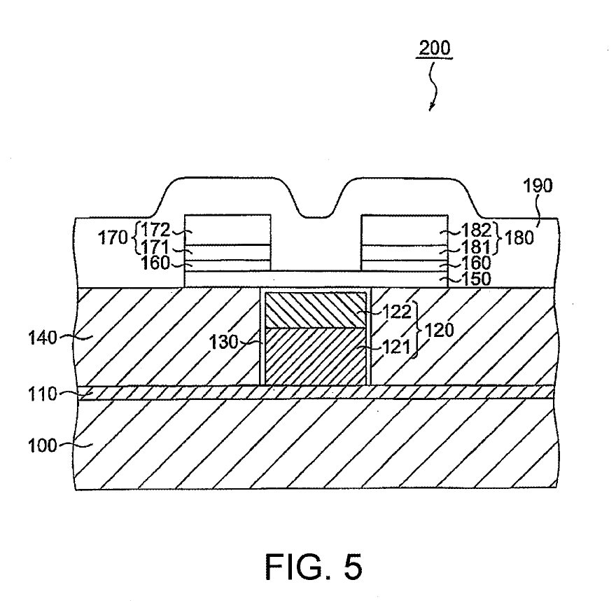

Next, referring to FIG. 5, the structure of a second embodiment of this invention and a manufacturing method thereof will be described. A thin film transistor (TFT) 200 according to the second embodiment of this invention comprises a Na-diffusion preventing film 110 formed on a soda glass substrate 100, a gate electrode/gate drive wiring layer 120 (gate electrode portion is shown in the figure) which is formed in a predetermined pattern on the Na-diffusion preventing film 110 and which comprises a lower layer 121 made of Al and an upper layer 122 made of an Al—Mg—Ce—Zr alloy, and a dense anodic oxide film 130 formed on surfaces of the gate electrode 120 by anodization using a non-aqueous solution. The illustrated TFT 200 further comprises a transparent resin layer 140 formed around the gate electrode/wiring layer 120 to approximately the same height as the gate electrode 12 and its upper-surface anodic oxide film 130 so as to be substantially flush with the upper-surface anodic oxide film 130, and an intrinsic amorphous silicon (i-aSi) layer 150 formed over the gate electrode 120 through the gate insulating film 130. The i-aSi layer 150 is provided with source and drain electrode connection regions.

Of the electrode connection regions, the source electrode connection region is provided with a high-concentration n-type amorphous silicon (n+-aSi) layer 160 and a source electrode 170 which is in contact with a surface of the layer 160 and which comprises a lower layer 171 formed of Zr and an upper layer 172 formed of Al. Likewise, the drain electrode connection region is provided with a high-concentration n-type amorphous silicon (n+-aSi) layer 160 and a drain electrode 180 which is in contact with a surface of the layer 160 and comprises a lower layer 181 formed of Zr and an upper layer 182 formed of Al. Exposed portions of the source electrode 170, the drain electrode 180, and the i-aSi layer 150 are covered with a SiCN protective film 190 which covers an upper surface of the device.

Next, a method of forming a thin film transistor of this embodiment configured as described above will be described with reference to FIG. 5. First, an inexpensive soda glass substrate 100 is prepared as a substrate. This glass substrate 100 is treated with a 0.5 vol % hydrofluoric acid aqueous solution for 10 seconds and then washed with pure water to remove, by lift-off, surface contamination. Then, a solution in which a composition of ((CH₃)SiO_{3/2})ₓ(SiO₂)₁₋ₓ (where 0<x≦1.0) is dissolved in an organic solvent is coated on a surface of the soda glass substrate 100 using a slit coater. Then, heating is carried out at a reduced pressure to completely remove the solvent. Specifically, heating is carried out at 400° C. at a reduced pressure of 5 Torr (665 Pa). In this manner, a transparent alkali diffusion preventing layer 110 with a thickness of 0.2 μm to 0.3 μm is formed. Then, an Al layer 121 is formed by sputtering to a thickness of 1.5 to 2.0 μm on the alkali diffusion preventing film 110 on the substrate and, thereon, an Al alloy layer (containing, in mass %, 4.5% Mg, 1% Ce, 0.1% Zr, and the balance of Al) 122 is formed by sputtering to a thickness of 0.5 to 1.5 μm. Then, a photoresist (not illustrated) is coated thereon and then is left in a predetermined pattern (gate electrode and gate drive wiring pattern) by known exposure and development and then, using it as a mask, the Al layer 121 and the Al alloy layer 122 are formed into a predetermined gate electrode/wiring pattern 120 by dry etching. Then, the resist is removed and anodization using a non-aqueous solution is applied to surfaces of the gate electrode/wiring layer 120, thereby forming an anodic oxide film 130.

Likewise as described above, the Al layer 121 and the Al alloy layer 122 in this embodiment may contain 0.01% or less, in mass %, of each of unavoidable impurity elements such as Si, Fe, Cu, Mn, Cr, and Zn. Further, likewise as described above, the Al alloy layer 122 may be such that, in mass %, the Mg concentration is 5.0% or less, the Ce concentration is 15% or less, the Zr concentration is 0.15% or less, and the balance comprises Al and unavoidable impurities. Preferably, the alloy layer 122 may be such that, in mass %, the Mg concentration is more than 0.01% and 5.0% or less, the Ce concentration is more than 0.01% and 5.0% or less, the Zr concentration is more than 0.01% and 0.15% or less, and the balance comprises Al and unavoidable impurities.

In this embodiment, on the surfaces of the Al layer 121 and the Al alloy layer 122, an Al₂O₃ film is formed to a thickness of 0.05 μm to 0.1 μm as the anodic oxide film 130 by the anodization using the non-aqueous solution. This corresponds to 0.025 μm to 0.05 μm in EOT as a gate insulating film. The non-aqueous solution used is composed of 79% ethylene glycol as a solvent and 20% pure water and 1.0% adipic acid (volume ratio) as solutes or is composed of 79.5% diethylene glycol, 20% pure water, and 0.5% adipic acid. At room temperature in the case of using the former or at 50° C. in the case of the latter, anodization is first carried out in a constant current mode at a current density of 0.1 mA/cm² to 0.2 mA/cm² and then anodization is carried out in a constant voltage mode at a voltage of 60V to 30V. Then, an anodic oxide film is heat-treated in an atmosphere of a nitrogen gas and an oxygen gas at 300° C. for about 1 hour.

Then, a solution in which an alkali-soluble alicyclic olefin-based resin composition is dissolved in a solvent is coated around the gate electrode/wiring layer 120 using a slit coater so as to exceed the height of the anodic oxide film 130 on the upper surface of the gate electrode 120, thereby forming a transparent organic insulating film. Then, in a microwave-excited plasma processing apparatus, a krypton gas and an oxygen gas are introduced into the apparatus and further a microwave is introduced into the apparatus to generate a plasma, thereby etching the entire surface of the transparent organic insulating film to expose a surface of the gate insulating film 130. In this event, the exposed surface of the gate insulating film 130 is exposed to oxygen radicals generated by the plasma so as to be oxidized so that the film quality is improved. In this manner, a transparent organic insulating film 140 being flush with the surface of the gate insulating film 130 is formed.

As described before, in a microwave-excited plasma processing apparatus, using the PECVD method, an intrinsic amorphous silicon film is formed to 0.02 to 0.1 μm on the surface of the gate insulating film 130 and a surface of the transparent organic insulating film 140 which are flat, and further, an n+ amorphous silicon film is continuously deposited thereon to 0.05 to 0.1 μm. Further, Zr is deposited thereon to 0.1 to 0.2 μm and Al is continuously deposited thereon to 0.5 μm. Then, the Al/Zr/n+ amorphous silicon films and the intrinsic amorphous silicon film are all removed except for a predetermined pattern (over the gate electrode 120 and its peripheral portion) by the photolithography method and the known RIE method. In this manner, an intrinsic amorphous silicon film 150 having the predetermined pattern (over the gate electrode 120 and its peripheral portion) is formed. Subsequently, the Al/Zr/n+ amorphous silicon films are etched and removed at a portion other than source and drain so as to separate the source and the drain, thereby forming n+ amorphous silicon films 160, an Al/Zr source electrode 170, and an Al/Zr drain electrode 180 in source and drain regions. Then, a SiCN film 190 is formed as a protective film by the PECVD method.

Wiring contact with the source and drain electrodes 170 and 180 is established by providing through holes in the SiCN film 190.

In the TFT 200 obtained according to the second embodiment, the Ce-containing Al alloy layer 122 is provided as an upper layer of the gate electrode 120. With the Ce-containing Al layer 122 thus provided, it is possible to form a dense and high-quality anodic oxide film as compared with the case of the Al layer 121 alone. Therefore, there is an advantage in that the anodic oxide film 130 formed on the Ce-containing Al layer 122 can be dense and of high quality (with high insulation performance and thus with high voltage resistance even if it is thin).

Further, in the first and second embodiments, the alloy layer containing Mg, Ce, Zr, and Al has been described as the Ce-added Al alloy layer to be formed with the anodic oxide film. In particular, the Al alloy layer containing 4.5% Mg-1% Ce-0.1% Zr has been described. However, there is considered a case where the gate electrode/wiring requires a higher electrical conductivity than that of the above-mentioned Ce-added Al alloy layer or requires a lower electrical resistivity than that of the above-mentioned Ce-added Al alloy layer. In this connection, the CeAI alloy layer containing 4.5% Mg-1% Ce-0.1% Zr has an electrical conductivity of 18.71×10⁶ (Ω⁻¹·m⁻¹) and an electrical resistivity of 5.24×10⁻⁸ (Ω·m). On the other hand, an Al layer free of Mg and so on has an electrical conductivity of 38.32×10⁶ (Ω⁻¹·m⁻¹) and an electrical resistivity of 2.60×10⁻⁸ (Ω·m).

According to an experiment by the present inventor, it has been found that if a Zr—Al alloy layer free of Mg is used as an Al alloy layer, it is possible to obtain a Ce-added Al alloy layer having an electrical conductivity and an electrical resistivity close to those of the Al layer. That is, it has been found that an Al alloy layer containing 0.1% Zr shows an electrical conductivity of 35.76×10⁶ (Ω⁻¹·m⁻¹) and an electrical resistivity of 2.79×10⁻⁸ (Ω·m), that an Al alloy layer containing 1% Ce-0.1% Ze shows an electrical conductivity of 34.86×10⁶ (Ω⁻¹·m⁻¹) and an electrical resistivity of 2.86×10⁻⁸ (Ω·m), and that an Al alloy layer containing 2% Ce-0.1% Ze shows an electrical conductivity of 33.61×10⁶ (Ω⁻¹·m⁻¹) and an electrical resistivity of 2.97×10⁻⁸ (Ω·m).

In this manner, using the Al alloy layer free of Mg and Ce and containing only Zr, it is possible to obtain the Al alloy layer having the electrical conductivity and the electrical resistivity very close to those of the Al layer. However, as described before, the weight loss ratio of an anodic oxide film due to corrosion by a corrosive gas becomes large. On the other hand, it has been confirmed that, with the Ce—Zr-added Al alloy layer free of Mg, a dense and high-quality anodic oxide film is formed and that its weight loss ratio due to corrosion is small.

Therefore, the Ce—Zr-added Al alloy layer not only can make small the electrical resistance of the gate electrode/wiring, but also can form a flat and high-quality gate insulating film by anodization.

In the above-mentioned example, the description has been made about the case where the Ce—Zr-added Al alloy layer is used in place of the single-layer Ce-added Al alloy layer shown in the first embodiment, but the Ce—Zr-added Al alloy layer can be used in place of the Al alloy layer 122 shown in FIG. 5.

While the exemplary embodiments of this invention and the manufacturing processes thereof have been shown above, this invention is not limited thereto. For example, if necessary, a silicon nitride film or the like may be formed by CVD on the surface of the upper-surface anodic oxide insulating film 13, 130, thereby providing a composite gate insulating film. Further, although the Ce-added Al alloy is used as the gate electrode/wiring in the embodiments, another Al alloy or pure Al may be used or an electrode of another material may be used inside of the gate electrode/wiring or in the lower part thereof. In summary, it is sufficient that at least an upper surface of a gate electrode or wiring is made of Al or an Al alloy and that its surface is oxidized by anodization using a non-aqueous solution and is used as at least a part of a gate insulating film.

### INDUSTRIAL APPLICABILITY

This invention is applied to display devices such as a liquid crystal display device, an organic EL device, and an inorganic EL device and capable of increasing the size of those display devices, and is also applicable to wiring of other than the display devices.

### DESCRIPTION OF SYMBOLS

10, 100: transparent substrate
11, 110: Na-diffusion preventing layer
12, 120: gate electrode/wiring layer
13, 130: anodic oxide film
14, 140: transparent resin film
15: semiconductor layer
16: electrode contact layer
17: source wiring layer
18: drain wiring layer

1. A semiconductor device comprising a gate electrode that is provided on a substrate and contains Al and/or an Al alloy, a gate insulating film that covers at least an upper surface of the gate electrode and includes an anodic oxide film obtained by anodizing the Al and/or the Al alloy of the gate electrode, and an insulator layer that surrounds the gate electrode on the substrate and that has a thickness equal to a total of a thickness of the gate electrode and a thickness of the gate insulating film on the upper surface of the gate electrode.

2. The semiconductor device according to claim 1, wherein the gate electrode contains the Al alloy which contains at least Zr and Ce among Mg, Zr, and Ce.

3. The semiconductor device according to claim 1, wherein the anodic oxide film of the gate insulating film is obtained by anodizing the Al alloy of the gate electrode, the Al alloy containing at least Zr and Ce among Mg, Zr, and Ce.

4. The semiconductor device according to claim 1, wherein the anodic oxide film is a non-porous anodic oxide film formed by anodization using a non-aqueous solution.

5. The semiconductor device according to claim 1, wherein the substrate is a transparent insulator substrate and the insulator layer is a transparent resin layer.

6. The semiconductor device according to claim 5, wherein the resin layer contains one or more kinds of resins selected from the group consisting of an acrylic-based resin, a silicone-based resin, a fluorine-based resin, a polyimide-based resin, a polyolefin-based resin, an alicyclic olefin-based resin, and an epoxy-based resin.

7. The semiconductor device according to claim 5, wherein the resin layer is formed of an alkali-soluble alicyclic olefin-based resin composition.

8. The semiconductor device according to claim 5, wherein the substrate comprises an alkali glass and an alkali diffusion preventing film formed thereon.

9. The semiconductor device according to claim 8, wherein the alkali diffusion preventing film is a transparent insulator coating film.

10. The semiconductor device according to claim 9, wherein the insulator coating film is a film that is obtained by drying and baking a liquid coating film containing at least one of a metal organic compound and a metal inorganic compound and a solvent.

11. The semiconductor device according to claim 1, wherein the gate electrode has a two-layer structure comprising an Al layer and a layer of an Al alloy containing at least Zr and Ce among Mg, Zr, and Ce and the gate insulating layer includes a film formed by anodizing the Al alloy.

12. A method of manufacturing a semiconductor device, comprising:
forming a gate electrode film in a predetermined pattern on a transparent substrate using Al and/or an Al alloy;
anodizing a surface of the gate electrode by an anodization method using a non-aqueous solution; and
providing on the substrate a transparent insulator layer having a thickness equal to a total of a thickness of the gate electrode and a thickness of an anodic oxide film on its upper surface so as to surround the gate electrode.

13. The method of manufacturing the semiconductor device according to claim 12, wherein the providing the transparent insulator layer on the substrate comprises:
forming a material, that forms the transparent insulator film, so as to extend over the gate electrode from the transparent substrate; and
removing a surface of the material, that forms the transparent insulator film, using a plasma containing oxygen.

14. The method of manufacturing the semiconductor device according to claim 13, wherein the removing using the plasma comprises:
exposing the anodic oxide film on the gate electrode; and
modifying the exposed anodic oxide film by the plasma.

15. The method of manufacturing the semiconductor device according to claim 12, wherein:
the gate electrode film has a two-layer structure comprising an Al layer and a layer of an Al alloy containing at least Zr and Ce among Mg, Zr, and Ce and a gate insulating layer includes a film formed by anodizing the Al alloy.

16. A display device manufactured using the semiconductor device according to any one of claims 1 to 11.

17. A display device comprising:
a wiring that is provided on a substrate and contains Al and/or an Al alloy
an insulating film that is provided so as to cover at least an upper surface of the wiring and includes an anodic oxide film formed by anodizing the Al and/or the Al alloy forming the wiring; and
an insulator layer that is provided on the substrate so as to surround the wiring and has a thickness that is equal to a total of a thickness of the wiring and a thickness of the insulating film on the upper surface of the wiring.

18. A semiconductor device comprising a gate electrode containing an Al alloy and a gate insulating film including an anodic oxide film that is formed by anodizing the Al alloy of the gate electrode, wherein the Al alloy contains at least Zr and Ce among Mg, Zr, and Ce.
